(19) United States
(12) Patent Application Publication
(10) Pub. No.: US 2025/0218853 A1
(43) Pub. Date: Jul. 3, 2025

(54) CHIP EJECTOR

(71) Applicant: SAMSUNG ELECTRONICS CO., LTD., SUWON-SI (KR)

(72) Inventor: Sangjin LEE, Suwon-si (KR)

(21) Appl. No.: 18/916,018

(22) Filed: Oct. 15, 2024

(30) Foreign Application Priority Data
Jan. 2, 2024 (KR) 10-2024-0000492

(51) Int. Cl. H01L 21/683

(52) U.S. Cl. CPC H01L 21/6838; H01L 21/6836

(57) ABSTRACT

The chip ejector includes a chamber including an inner space, a holder disposed on the chamber, and having an upper surface and a lower surface opposite to the upper surface, a plurality of holes formed in the holder along a vertical direction, which is perpendicular to the first direction and the second direction and spaced apart from each other in the first direction, and the second direction and a pressurization unit providing pressurized air to a mount tape that is disposed on the holder. The pressurization unit includes at least one air pin inserted into at least one hole among the plurality of holes along the vertical direction and having a discharge hole extending along the vertical direction and an air inlet pipe fastened to the air pin and comprising at least one path through which a pressurized air flow is provided to the air pin.

### CROSS-REFERENCE TO RELATED APPLICATION

This application claims priority under 35 U.S.C. § 119 to Korean Patent Application No. 10-2024-0000492, filed on Jan. 2, 2024, in the Korean Intellectual Property Office, the disclosure of which is incorporated by reference herein in its entirety.

### 1. TECHNICAL FIELD

The present inventive concept relates to a chip ejector.

### 2. DISCUSSION OF THE RELATED ART

Generally, a semiconductor manufacturing process includes a die bonding process in which diced chips are detached and picked up from a wafer by a chip detaching device and then mounted on another wafer. During the process, chips on each tape (i.e., mount tape) are pushed up by a sharp pin.

When a thin chip (e.g., a chip having a horizontal and vertical width of 10 mm and a thickness of 30 μm or less) is pushed up by a sharp pin or the like, cracks or breaks may occur in the chip due to the end of the pin.

### SUMMARY

According to an aspect of the inventive concept, there is provided a chip ejector including a chamber including an inner space, a holder disposed on the chamber, extending along a first direction and a second direction perpendicular to the first direction, and having an upper surface and a lower surface opposite to the upper surface, a plurality of holes formed in the holder along a vertical direction, which is perpendicular to the first direction and the second direction and spaced apart from each other in the first direction, and the second direction and a pressurization unit providing pressurized air to a mount tape that is disposed on the holder. The pressurization unit includes at least one air pin inserted into at least one hole among the plurality of holes along the vertical direction and having a discharge hole extending along the vertical direction and an air inlet pipe fastened to the air pin and comprising at least one path through which a pressurized air flow is provided to the air pin.

According to another aspect of the inventive concept, there is provided a chip ejector including a holder extending along a first direction and a second direction perpendicular to the first direction and having a plurality of holes passing therethrough along a vertical direction, a mount tape disposed on an upper surface of the holder, a chip disposed on an upper surface of the mount tape, a picker unit disposed above the chip and vacuum-suctioning the chip to separate the chip from the mount tape, an air pin inserted into at least one hole among the plurality of holes and configured to provide pressurized air to a lower surface of the mount tape, an air inlet pipe on which the air pin is mounted to form a plurality of paths through which the pressurized air flows, a pressurization source providing the pressurized air to the air inlet pipe, a chamber disposed below the holder and forming an inner space and a vacuum unit configured to provide vacuum pressure to the lower surface of the mount tape.

According to another aspect of the inventive concept, there is provided a chip ejector including a chamber forming an inner space, a holder disposed above the chamber, and having a plurality of holes passing therethrough along a vertical direction, a mount tape disposed on an upper surface of the holder, a chip disposed on an upper surface of the mount tape, a picker unit disposed above the chip and vacuum-suctioning the chip to separate the chip from the mount tape, a pressurization unit providing pressurized air to the mount tape disposed on the holder and a vacuum unit providing vacuum pressure to a lower surface of the mount tape. The pressurization unit includes an air pin inserted into at least one hole among the plurality of holes along the vertical direction and having a discharge hole extending in the vertical direction, an air inlet pipe on which the air pin is mounted to form a plurality of paths through which the pressurized air flows, a pressurization source providing the pressurized air to the air inlet pipe and a pressurization valve connected to the pressurization source and regulating an amount of the pressurized air. A hole, into which the air pin is not inserted among the plurality of holes corresponding to an area of the chamber, is a suction hole. The vacuum unit includes a vacuum source generating the vacuum pressure in the suction hole and the inner space of the chamber connected to the suction hole and a vacuum valve connected to the vacuum source and regulating a level of the vacuum pressure.

### BRIEF DESCRIPTION OF THE DRAWINGS

FIG. 1 is a cross-sectional view of a chip ejector according to an embodiment of the present inventive concept.

FIG. 2 is a cross-sectional view of a chip ejector according to an embodiment of the present inventive concept.

FIG. 3 is a cross-sectional view schematically showing an operation of a chip ejector according to an embodiment of the present inventive concept.

FIG. 4 is a plan view of a chip ejector according to an embodiment of the present inventive concept.

FIG. 5 is a cross-sectional view schematically showing an operation of a chip ejector according to an embodiment of the present inventive concept.

FIG. 6 is a plan view of a chip ejector according to an embodiment of the present inventive concept.

FIG. 7 is a cross-sectional view schematically showing an operation of a chip ejector according to an embodiment of the present inventive concept.

FIG. 8 is a plan view of a chip ejector according to an embodiment of the present inventive concept.

FIG. 9 is a cross-sectional view schematically showing an operation of a chip ejector according to an embodiment of the present inventive concept.

FIG. 10 is a plan view of a chip ejector according to another embodiment of the present inventive concept.

FIG. 11 is a plan view showing a memory module including picked-up chips according to an embodiment of the present inventive concept.

FIG. 12 is a configuration diagram showing a system including picked-up chips according to an embodiment of the present inventive concept.

FIG. 13 is a configuration diagram showing a memory card including picked-up chips according to an embodiment of the present inventive concept.

FIG. 14 is a perspective view schematically showing an electronic device to which picked-up chips are applied according to an embodiment of the present inventive concept.

### DETAILED DESCRIPTION OF THE EMBODIMENTS

The embodiments of the present inventive concept may be embodied in various forms. Thus, the present inventive concept is not necessarily limited to the following embodiments. In addition, the present embodiments described below are only examples, and thus, various changes may be made from the embodiments.

All examples or illustrative terms are only used to explain the technical idea in detail, and thus, the scope of the inventive concept is not necessarily limited by these examples or illustrative terms unless limited by the claims.

Unless otherwise specified, in this specification, a vertical direction may be defined as a Z direction, and a first direction and a second direction may each be defined as a direction perpendicular to the Z direction. The first direction may be referred to as an X direction and the second direction may be referred to as a Y direction. A vertical level may refer to a height level along the vertical direction Z. A horizontal width may refer to a length along the horizontal direction X and/or Y and a vertical length may refer to a length along the vertical direction Z.

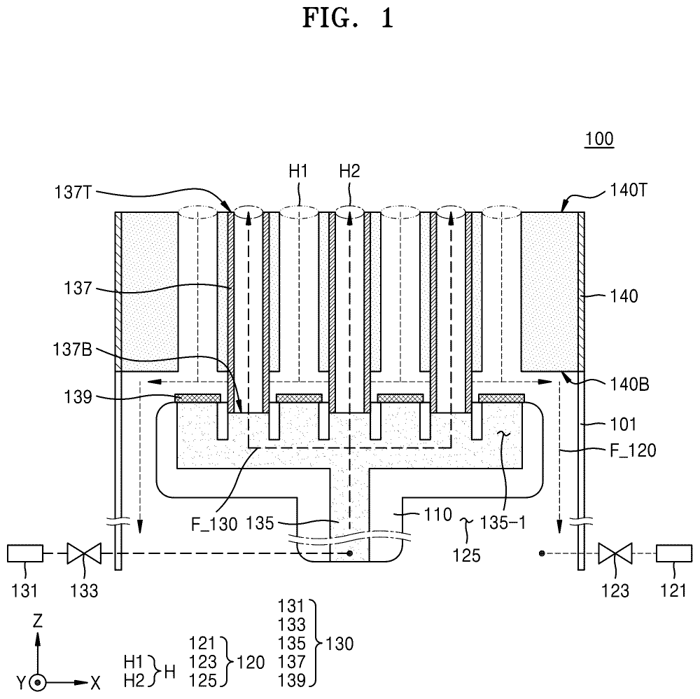

FIG. 1 is a cross-sectional view of a chip ejector 100 according to an embodiment of the present invention.

Referring to FIG. 1, the chip ejector 100 may include a chamber 101, which forms an inner space 125 and a holder 140 disposed above the chamber 101, extending along a first direction X and a second direction Y perpendicular to the first direction X, and having a plurality of holes H passing therethrough along a vertical direction Z.

The holder 140 may have an upper surface 140T and a lower surface 140B opposite to the upper surface 140T. The plurality of holes H may be formed through the holder 140. The plurality of holes H may extend from the upper surface 140T of the holder 140 towards the lower surface 140B of the holder 140 along the vertical direction Z, which is perpendicular to both the first direction X and the second direction Y. The plurality of holes H may be spaced apart from each other along the first direction X and the second direction Y. The horizontal cross-section of each of the plurality of holes H may have a circular shape. The number and thickness of the plurality of holes H passing through the holder 140 and the distance therebetween are not necessarily limited to those shown in FIG. 1.

The chip ejector 100 may include a pressurization unit 130. The pressurization unit 130 may include an air pin 137 that is inserted, along the vertical direction Z, into at least one hole H among the plurality of holes H. A plurality of air pins 137 may be provided.

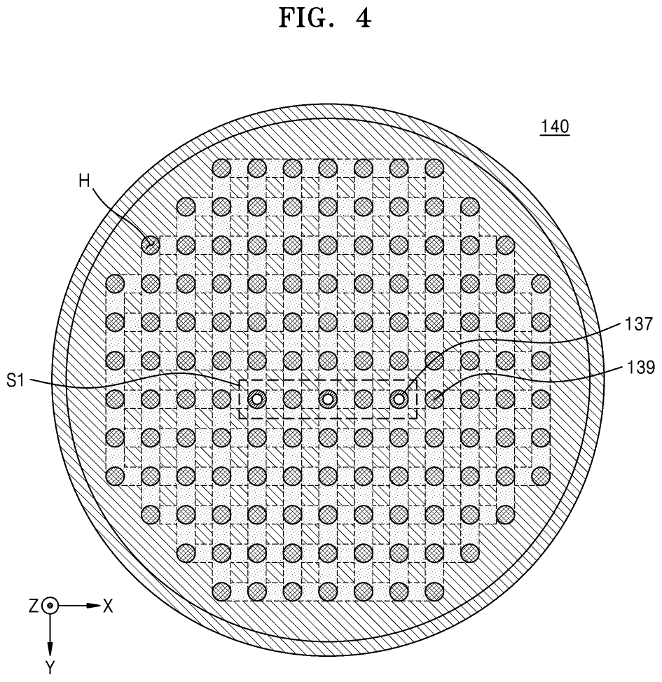

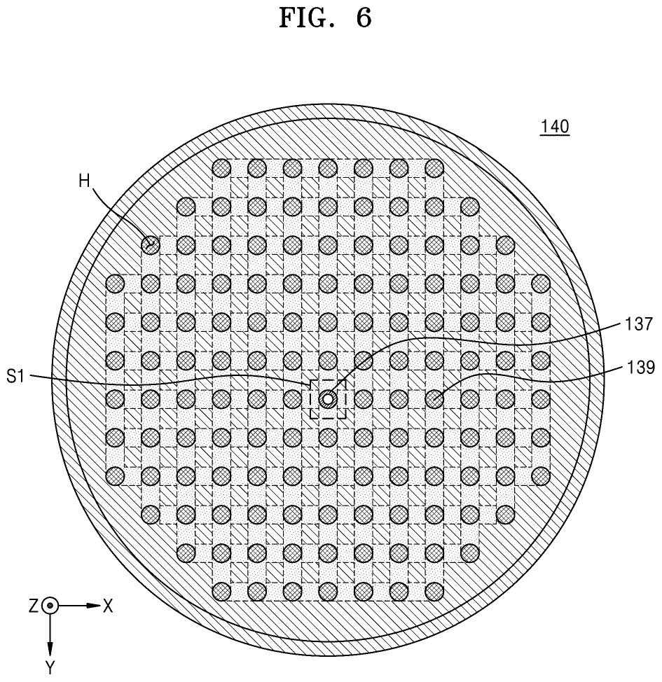

In embodiments of the present inventive concept, the number of air pins 137 may be three. The three air pins 137 may be spaced apart from each other along the first direction X. The three air pins 137 may be respectively inserted into and placed in the holes H of the holder 140. At least one hole H, into which the air pin 137 is not inserted, may be located between the air pins 137. For example, in FIG. 4, the chip ejector 100 at a first position S1 (refer to FIG. 6) may overlap, along the vertical direction Z, seven holes H formed in the holder 140. Here, when the seven holes H are defined as a first hole, a second hole, a third hole, a fourth hole, a fifth hole, a sixth hole, and a seventh hole respectively from the left, the three air pins 137 may be respectively inserted into the second hole, the fourth hole, and the sixth hole. However, the number and locations of the air pins 137 are not necessarily limited thereto. For example, the number of air pins 137 may be one, two, or four or more, and the air pins 137 may also be inserted into any of the holes H formed in the holder 140. According to embodiments of the inventive concept, the longest distance between the inserted air pins 137 along the first direction X may be substantially equal to or less than the length of a chip 400 along the first direction X.

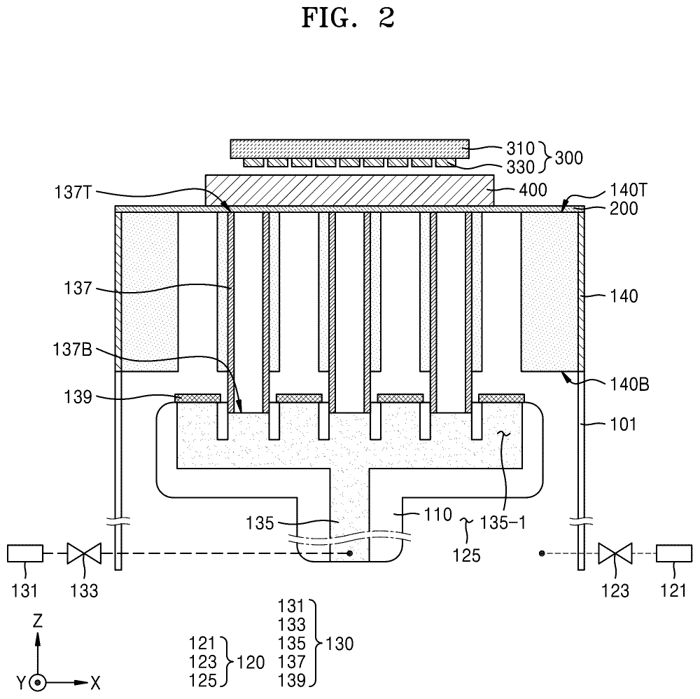

The air pin 137 may have an air pin upper surface 137T and an air pin lower surface 137B disposed opposite to the air pin upper surface 137T. The air pin 137 may include a discharge hole H2 extending from the air pin upper surface 137T towards the air pin lower surface 137B along the vertical direction Z. The discharge hole H2 may form a path along which a pressurized air flow F_130 moves, which is described below. The horizontal width of the discharge hole H2 may be constant along the vertical direction Z. In an embodiment of the present inventive concept, the air pin 137 including the discharge hole H2 may have a hollow cylindrical shape having a constant horizontal width along vertical direction Z. The horizontal width of the discharge hole H2 may be less than the horizontal width of the hole H. For example, the horizontal width of the discharge hole H2 may be less than the horizontal width of the hole H by an amount corresponding to the cross-sectional area of the air pin 137 inserted into the hole H. The air pin 137 may be inserted into the hole H so that the vertical level of the air pin upper surface 137T is equal to the vertical level of the upper surface 140T of the holder 140. The air pin 137 is inserted so that the vertical level of the air pin upper surface 137T is equal level to the vertical level of the upper surface 140T of the holder 140, and thus, a mount tape 200 and a chip 400 disposed on the upper surface of the mount tape 200 may have a constant vertical level, which is described below with reference to FIG. 2.

The pressurization unit 130 may include an air inlet pipe 135 fastened to the air pin 137. For example, the air pin lower surface 137B may be in contact with the air inlet pipe 135. The air inlet pipe 135 may be at least partially surrounded by a support 110. As used herein, the phrase “at least partially covering” may mean that the first element covers some or all of the second element. The air inlet pipe 135 and the support 110 may be arranged inside the chamber 101. In an embodiment of the present invention, the air inlet pipe 135 may include at least one path 135-1 that is coupled to the air pin 137 so as to provide the pressurized air flow F_130 to the air pin 137. Although seven paths 135-1 are shown in the diagram, the number and shape of the paths 135-1 and the distances between the paths 135-1 are not necessarily limited to those shown in the diagram. The air pin 137 is inserted into and fastened to the path 135-1, and the vertical level of the air pin lower surface 137B may be disposed at a lower level than the vertical level of the upper surface of the path 135-1.

The pressurization unit 130 may include a pressurization source 131, which provides the pressurized air to the air inlet pipe 135, and a pressurization valve 133 that is connected to the pressurization source 131 and regulating the amount of pressurized air. The pressurized air provided by the pressurization source 131 may form the pressurized air flow F_130 with respect to each of the plurality of paths 135-1 formed in the air inlet pipe 135 and the air pins 137 fastened to the paths 135-1. The pressurized air flow F_130 may reach the air pin upper surface 137T and provide the pressurized air to the lower surface of the mount tape 200, which is described below with reference to FIG. 2. The pressurization valve 133 may be repeatedly opened and closed. For example, the chip ejector 100 may repeatedly switch on and off the pressurized air flow F_130 that travels through the discharge hole H2 when separating the chip 400 from the mount tape 200, which is described below with reference to FIG. 2. The pressurized air flow F_130 may be switched on and off in a time of, for example, tens of milliseconds (ms).

The pressurization unit 130 may include at least one cap 139 that is mounted on the upper surface of a path 135-1 to which the air pin 137 is not fastened among the plurality of paths 135-1 provided by the air inlet pipe 135. In FIG. 1, when the plurality of paths 135-1 are defined as first to seventh paths in this order from the left, the caps 139 are mounted on the upper surfaces of the first path, the third path, the fifth path, and the seventh path among the plurality of paths 135-1 and may isolate the inner space 125 defined by the chamber 101 from the space of the air inlet pipe 135 surrounded by the support 110. For example, even if the pressurized air flow F_130 moves to the path 135-1 on which the cap 139 is mounted, the pressurized air flow F_130 may be prevented from leaking into the inner space 125 by the cap 139. For example, the cap 139 may include a rubber material that is deformed in shape and less stressed when an external force is applied thereto, but the present inventive concept is not necessarily limited thereto. The chip ejector 100 may include a vacuum unit 120.

In the vacuum unit 120, the hole H, into which the air pin 137 is not inserted among the plurality of holes H corresponding to the area of the chamber 101, is a suction hole H1. In FIG. 1, when the plurality of holes H are including first to seventh holes in this order from the left, the first hole, the third hole, the fifth hole, and the seventh hole may be suction holes H1. The vacuum unit 120 may provide a vacuum flow F_120 to the suction holes H1 and the inner space 125 of the chamber 140 connected to the suction hole H1.

The vacuum unit 120 may further include a vacuum source 121 generating vacuum pressure and a vacuum valve 123 connected to the vacuum source 121 and controlling the level of the vacuum pressure. The vacuum valve 123 may be repeatedly opened and closed. For example, the chip ejector 100 may repeatedly switch on and off the vacuum flow F_120 that travels through the discharge hole H2 when separating the chip 400 from the mount tape 200, which is described below with reference to FIG. 2. The vacuum flow F_120 may be switched on and off in a time of, for example, tens of milliseconds (ms). The vacuum flow F_120 may provide the vacuum pressure to the lower surface of the mount tape 200, which is be described below with reference to FIG. 2.

FIG. 2 is a cross-sectional view of a chip ejector according to an embodiment of the present inventive concept.

Referring to FIG. 2 together with FIG. 1, the mount tape 200 may be placed on the upper surface of the holder 140. At least one chip 400 may be disposed on the upper surface of the mount tape 200. In an embodiment of the present inventive concept, the chip 400 may include a semiconductor chip. The chip ejector 100 may be disposed below the mount tape 200. According to embodiments of the present inventive concept, the mount tape 200 may be supported by the chip ejector 100. For example, the mount tape 200 may be supported by the holder 140.

The chip ejector 100 may include a picker unit 300 which is disposed above the chip 400. The chip ejector 100 may vacuum-suction the chip 400 and separate the chip 400 from the mount tape 200. The picker unit 300 may include a picker vacuum part 330, which provides the vacuum pressure to the upper surface of the chip 400, and a picker body part 310 which is disposed on the upper surface of the picker vacuum part 330. The picker vacuum part 330 may be spaced apart from the upper surface of the chip 400 by a distance, and the horizontal width of the picker body part 310 and the picker vacuum part 330 may be less than the horizontal width of the chip 400. The picker body part 310 may move the picker vacuum part 330 along horizontal and vertical directions and pick up the chip 400. The chip 400 picked up as described above may be conveyed onto a chip stage, and the chip 400 that is on the chip stage may be bonded to a substrate by a bonding module. The picker vacuum part 330 may have a plurality of suction holes for vacuum-suctioning the upper surface of the chip 400. The chip 400 may be vacuum-suctioned onto the lower surface of the picker vacuum part 330 by the suction holes. The suction holes may be connected to the vacuum source 121 or connected to another vacuum source.

The chip 400 may include a conductive region, for example, a well that is doped with impurities or a structure that is doped with impurities. A semiconductor device layer including individual devices may be provided on an active surface of the chip 400. The individual devices may include, for example, transistors. The individual devices may include microelectronic devices, for example, metal-oxide-semiconductor field effect transistors (MOSFET), system large scale integration (LSI), image sensors, such as complementary metal-oxide-semiconductor (CMOS) imaging sensors (CIS), micro-electro-mechanical systems (MEMS), active devices, passive devices, etc.

The chip 400 may include a memory chip or a logic chip. The memory chip may include volatile memory semiconductor devices, such as dynamic random access memory (DRAM) and static random access memory (SRAM), or non-volatile memory semiconductor devices, such as phase-change random access memory (PRAM), magnetoresistive random access memory (MRAM), ferroelectric random access memory (FeRAM), and resistive random access memory (RRAM). The logic chip may include a central processing unit (CPU) chip, a graphics processing unit (GPU) chip, an application processor (AP) chip, or an application specific integrated circuit (ASIC) chip.

The substrate including the chip 400 may include a semiconductor material, such as silicon (Si) and germanium (Ge). In addition, the semiconductor substrate may include compound semiconductor materials, such as silicon carbide (SiC), gallium arsenide (GaAs), indium arsenide (InAs), and indium phosphide (InP). The semiconductor substrate may include a conductive region, for example, wells doped with impurities. The semiconductor substrate may have various device isolation structures, such as a shallow trench isolation structure.

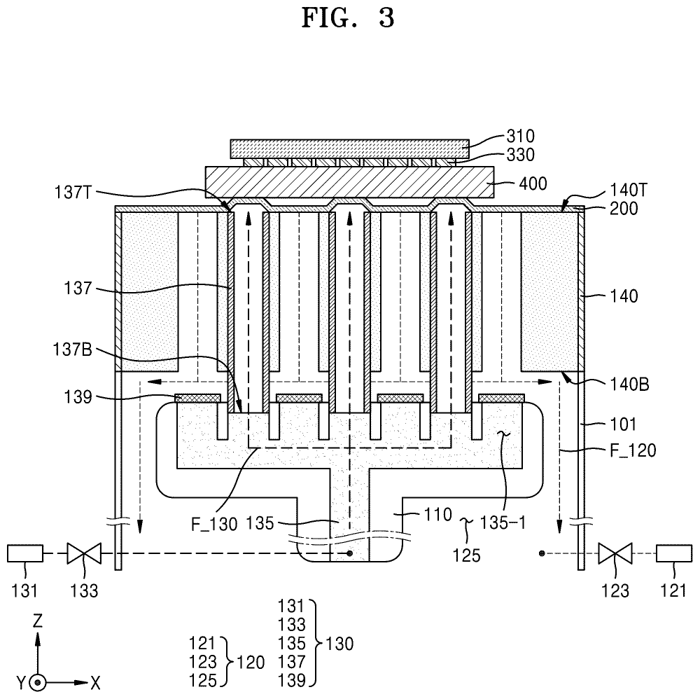

FIG. 3 is a cross-sectional view schematically showing an operation of a chip ejector according to an embodiment of the present inventive concept. Hereinafter, to the extent that an element has not been described in detail, it may be assumed that the element is at least similar to corresponding elements that have been described in previous figures.

Referring to FIG. 3, the mount tape 200 may be disposed on the upper surface 140T of the holder 140 having a plurality of holes, and the chip 400 may be disposed on the upper surface of the mount tape 200. The pressurized air is provided by the pressurization source 131, and the provided pressurized air generates the pressurized air flow F_130 in the air inlet pipe 135 and the air pin 137.

The generated pressurized air flow F_130 may raise the mount tape 200 only in an area corresponding to the horizontal cross-sectional area of the air pin 137. While the mount tape 200 is rising, the vacuum source 121 may provide the vacuum pressure to a hole into which the air pin 137 is not inserted, for example, a suction hole, thereby forming the vacuum flow F_120. Therefore, even if the pressurized air is provided by the pressurization source 131, the mount tape 200 in a region corresponding to the hole into which the air pin 137 is not inserted might not rise. For example, only a designated region of the mount tape 200 may be raised. For example, when the pressurized air is provided to the air pin 137, the chip ejector 100 may change to the state as shown in the diagram. The pressurized air flow F_130 flowing along the air inlet pipe 135 and the air pin 137 may apply pressure upward along the vertical direction Z onto the lower surface of the mount tape 200. Due to this pressure, a portion of the mount tape 200, which has the area corresponding to the discharge hole of the air pin 137, may be pushed upward along the vertical direction Z. In addition, a portion of the mount tape 200, which is not in contact with the air pin 137, for example, a portion of the mount tape 200 corresponding to the suction hole, may maintain the vertical level without being pushed upward. As the portion of the mount tape 200, which has the area corresponding to the discharge hole of the air pin 137, is pushed upward along the vertical direction Z, the chip 400 on the upper surface of the mount tape 200 may be detached from the mount tape 200.

In the chip ejector 100 according to embodiments of the present inventive concept, the air pin 137 pushes the mount tape 200 upward along the vertical direction Z through the pressurized air flow F_130 having relatively low stress. Consequently, the pressure may be applied uniformly onto the lower surface of the mount tape 200. Accordingly, the mount tape 200 may be also pushed upward along the vertical direction Z while maintaining a horizontal state without being tilted or rotated. In addition, the chip 400 on the upper surface of the mount tape 200 may be detached from the mount tape 200 while maintaining a horizontal state. Therefore, the occurrence of cracks or pick-up failure may be prevented when the chip 400 is detached from the mount tape 200 using a die bonder or the like. In addition, the mounting position and air pressure of the air pin 137 may be freely adjusted, and thus, pressure appropriate for the size of the provided chip 400 may be applied to the mount tape 200.

The picker vacuum part 330 may be lowered by the picker body part 310 to a position spaced a certain distance apart from the upper surface of the chip 400 to be picked up. Although the diagram shows that the vertical levels of the picker vacuum part 330 and the picker body part 310 are fixed and only the vertical level of the chip 400 rises, the embodiment is not necessarily limited thereto. For example, the chip 400 may be raised along the vertical direction Z by a certain distance due to the pressurized air flow F_130 supplied by the air pin 137. In addition, as used herein, the upper surface of the chip 400 to be picked up refers to the upper surface of the chip 400 that has already risen. In addition, the vacuum may be provided to the suction holes from the vacuum source 121, and thus, the mount tape 200 may be vacuum suctioned onto the upper surface 140T of the holder 140.

FIG. 4 is a plan view of a chip ejector according to an embodiment of the present inventive concept. Hereinafter, to the extent that an element has not been described in detail, it may be assumed that the element is at least similar to corresponding elements that have been described in previous FIGS. 1 to 3.

Referring to FIG. 4, the holder 140 may have a circular shape extending along the first direction X and the second direction Y. The holder 140 may have the plurality of holes H passing through the holder 140 along the vertical direction Z. In a plan view, the plurality of holes H may be spaced apart from each other by a certain distance along the first direction X and the second direction Y. The horizontal cross-section of the hole H may have a circular shape.

The air pin 137 may be inserted into the hole H of the holder 140. According to embodiments of the present inventive concept, the cross-sectional footprint of the air pin 137 on the X-Y plane may be smaller than the area of the hole H. The length of the air pin 137 along the vertical direction Z may be greater than the length of the holder 140 of FIG. 1 along the vertical direction Z.

The chip ejector 100 may be located at a first position S1, and the first position S1 may correspond to the horizontal width of the chip 400 of FIGS. 2 and 3. Referring to FIG. 1 together with FIG. 4, the chip ejector 100 may overlap seven holes among the plurality of holes H. In addition, when the seven holes H are defined as a first hole, a second hole, a third hole, a fourth hole, a fifth hole, a sixth hole, and a seventh hole respectively from the left, the three air pins 137 may be respectively inserted into the second hole, the fourth hole, and the sixth hole. The air pin 137 might be not inserted into the first hole, the third hole, the fifth hole, and the seventh hole, and the vacuum flow F_120 may be provided in the first hole, the third hole, the fifth hole, and the seventh hole which refer to the suction holes H1. In a plan view, substantially no structure may be installed or provided in the holes H defined as the suction holes H1, and thus, the upper surface of the cap 139 may be exposed. Accordingly, the upper surfaces of the caps 139 may be exposed in the plurality of holes into which the air pins 137 might not be inserted.

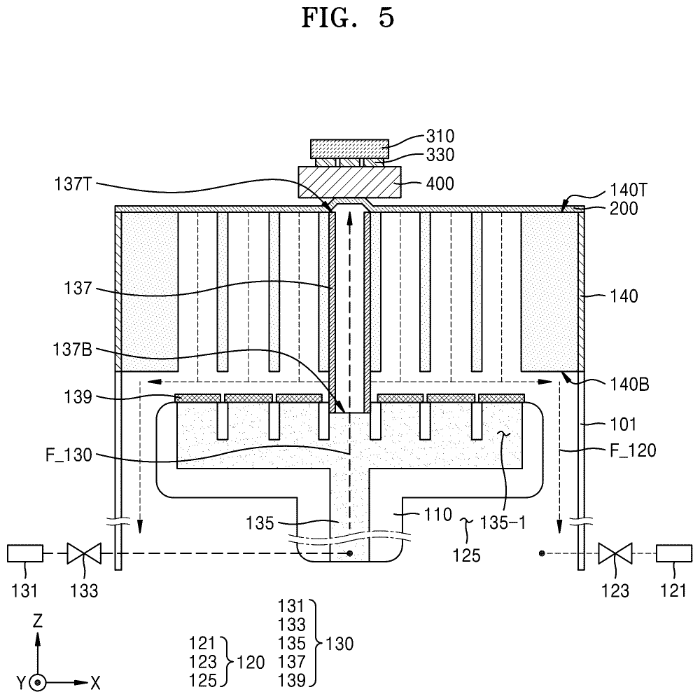

FIG. 5 is a cross-sectional view schematically showing an operation of a chip ejector according to another embodiment. FIG. 6 is a plan view of the chip ejector according to another embodiment. To the extent that an element has not been described in detail, it may be assumed that the element is at least similar to corresponding elements that have been described in previous FIGS. 1 to 4.

Referring to FIGS. 5 and 6, the chip ejector may be located at a first position S1, and the first position S1 may correspond to the horizontal width of a chip 400 of FIG. 5. Referring to FIG. 1 together with FIGS. 5 and 6, the chip ejector 100 may overlap seven holes among the plurality of holes H. Here, when the seven holes H are arranged as a first hole, a second hole, a third hole, a fourth hole, a fifth hole, a sixth hole, and a seventh hole respectively from the left, the air pin 137 may be inserted into the fourth hole. When the seven paths 135-1 of the air inlet pipe 135 are arranged as a first path, a second path, a third path, a fourth path, a fifth path, a sixth path, and a seventh path respectively from the left, the air pin 137 may be inserted into the fourth path. The number of inserted air pins 137 may be singular, but the present inventive concept is not necessarily limited thereto.

The cap 139 may be disposed on the upper surface of the path 135-1 into which the air pin 137 is not inserted. The caps 139 may be arranged on the first path, the second path, the third path, the fifth path, the sixth path, and the seventh path. The pressurized air flow F_130 generated by the pressurized air provided by the pressurization source 131 may move along the air pin 137 inserted into the fourth path. In the first path, the second path, the third path, the fifth path, the sixth path, and the seventh path in which the caps 139 are arranged, the pressurized air flow F_130 may move but might not reach the lower surface of the mount tape 200 due to the caps 139 that isolate the air inlet pipe 135 from the inner space 125 of the chamber 101.

The first hole, the second hole, the third hole, the fifth hole, the sixth hole, and the seventh hole into which the air pins 137 are not inserted may be provided with the vacuum flow F_120 and function as the suction holes H1 (refer to FIG. 1).

The cross-sectional area of the chip 400 in FIG. 5 may be greater than the cross-sectional area of the hole into which the air pin 137 is inserted. The mount tape 200 disposed on the lower surface of the chip 400 may be raised by a certain vertical level. The generated pressurized air flow F_130 may raise the mount tape 200 only in an area corresponding to the horizontal cross-sectional area of the air pin 137. While the mount tape 200 is rising, the vacuum source 121 may provide the vacuum pressure to the hole into which the air pin 137 is not inserted, for example, the suction hole H1 (FIG. 1), thereby forming the vacuum flow F_120. In an embodiment of the present inventive concept, the pressurization unit 130 and the vacuum unit 120 may be configured to operate together. Therefore, even if the pressurized air is provided by the pressurization source 131, the mount tape 200 in a region corresponding to the hole into which the air pin 137 is not inserted might not rise. For example, only a designated region of the mount tape 200 may be raised. For example, when the pressurized air is provided to the air pin 137, the chip ejector 100 may change to the state as shown in the diagram. The horizontal area of the raising mount tape 200 may be less than the horizontal area of the chip 400.

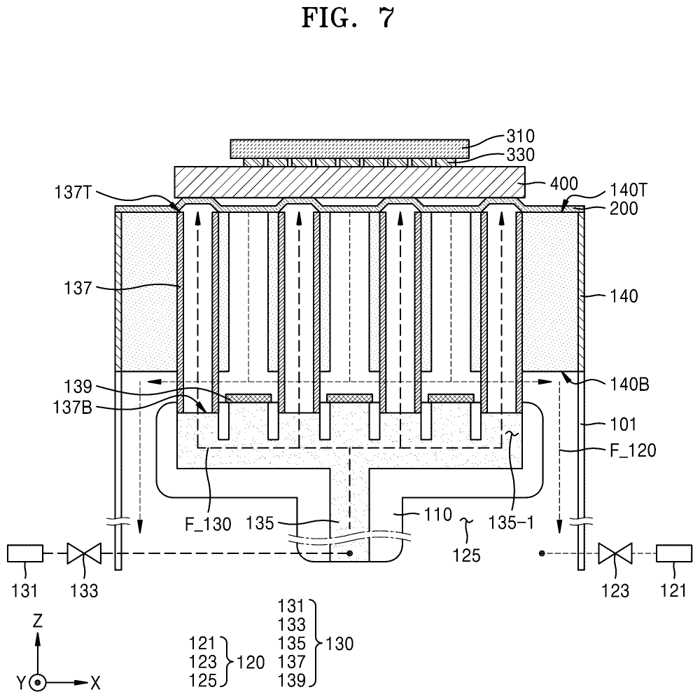

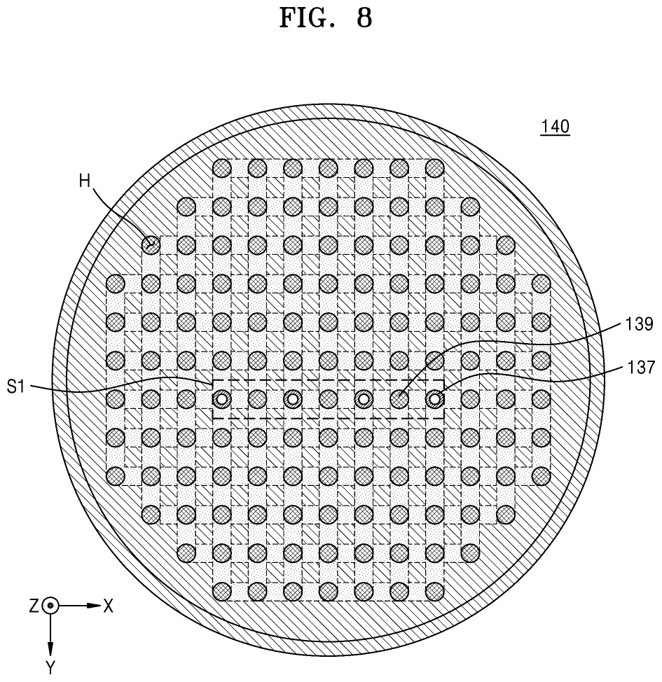

FIG. 7 is a cross-sectional view schematically showing an operation of a chip ejector according to an embodiment of the present inventive concept. FIG. 8 is a plan view of the chip ejector according to another embodiment of the present inventive concept. To the extent that an element has not been described in detail, it may be assumed that the element is at least similar to corresponding elements that have been described in FIGS. 1 to 6.

Referring to FIGS. 7 and 8, the chip ejector may be located at a first position S1, and the first position S1 may correspond to the horizontal width of a chip 400 of FIG. 7. Referring to FIG. 1 together with FIGS. 7 and 8, the chip ejector 100 may overlap seven holes among the plurality of holes H. Here, when the seven holes H are arranged as a first hole, a second hole, a third hole, a fourth hole, a fifth hole, a sixth hole, and a seventh hole respectively from the left, the air pins 137 may be respectively inserted into the first hole, the third hole, the first hole, and the seventh hole. For example, when the seven paths 135-1 of the air inlet pipe 135 are arranged as a first path, a second path, a third path, a fourth path, a fifth path, a sixth path, and a seventh path from the left, the air pins 137 may be respectively inserted into the first path, the third path, the fifth path, and the seventh path. The number of inserted air pins 137 may be plural, but the present inventive concept is not necessarily limited thereto.

The cap 139 may be disposed on the upper surface of the path 135-1 into which the air pin 137 is not inserted. The caps 139 may be disposed on the second path, the fourth path, and the sixth path. The pressurized air flow F_130 generated by the pressurized air provided by the pressurization source 131 may move along the air pins 137 inserted into the first path, the third path, the fifth path, and the seventh path. In the second path, the fourth path, and the sixth path in which the caps 139 are arranged, the pressurized air flow F_130 may move but might not reach the lower surface of the mount tape 200 due to the caps 139 that isolate the air inlet pipe 135 from the inner space 125 of the chamber 101.

The second hole, the fourth hole, and the sixth hole into which the air pins 137 are not inserted may be provided with the vacuum flow F_120 and function as the suction holes H1 (refer to FIG. 1).

The cross-sectional area of the chip 400 in FIG. 7 may be greater than the cross-sectional areas of the holes into which the air pins 137 are inserted. The mount tape 200 disposed on the lower surface of the chip 400 may be raised by a certain vertical level. The generated pressurized air flow F_130 may raise the mount tape 200 only in areas corresponding to the horizontal cross-sectional areas of the air pins 137. While the mount tape 200 is rising, the vacuum source 121 may provide the vacuum pressure to the hole into which the air pin 137 is not inserted, for example, the suction hole H1 (FIG. 1), thereby forming the vacuum flow F_120. In an embodiment of the present inventive concept, the pressurization unit 130 and the vacuum unit 120 may be configured to operate together. Therefore, even if the pressurized air is provided by the pressurization source 131, the mount tape 200 in a region corresponding to the hole into which the air pin 137 is not inserted might not rise. For example, only a region of the mount tape 200 may be raised. For example, when the pressurized air is provided to the air pin 137, the chip ejector 100 may change to the state as shown in the diagram. In addition, the horizontal area of the raising mount tape 200 may be less than the horizontal area of the chip 400.

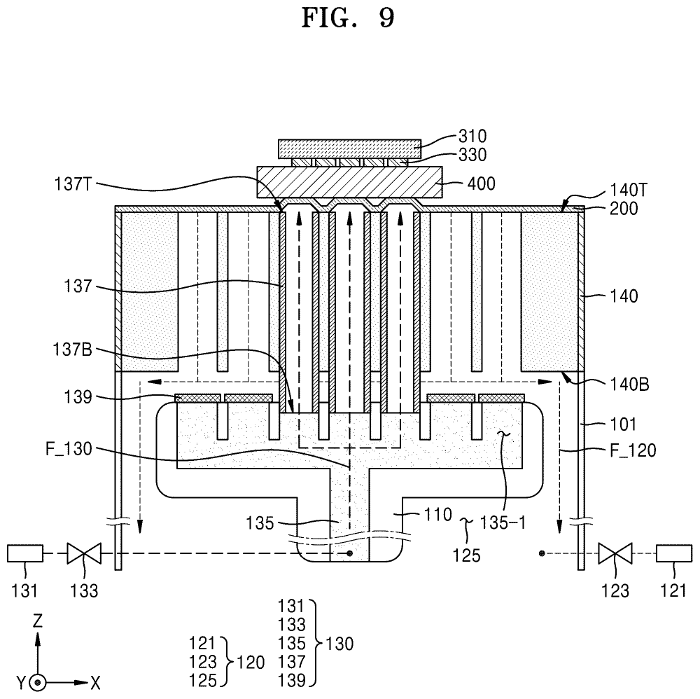

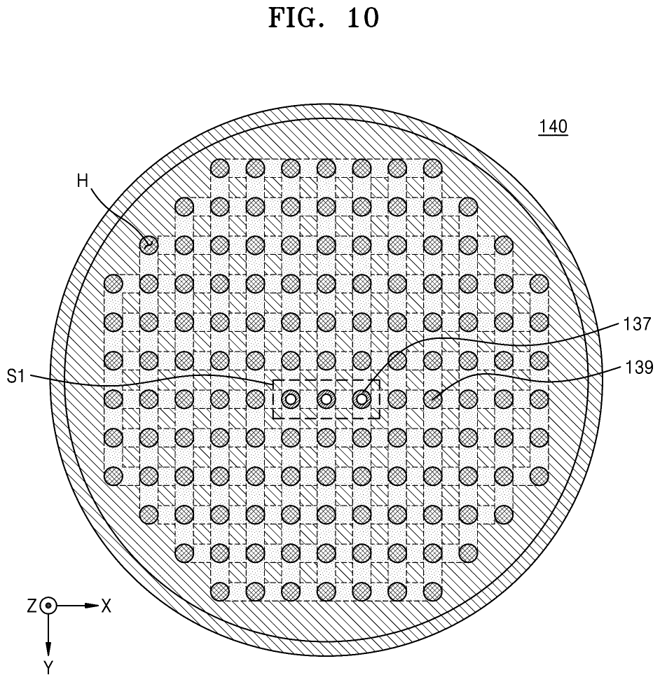

FIG. 9 is a cross-sectional view schematically showing an operation of a chip ejector according to an embodiment of the present inventive concept. FIG. 10 is a plan view of the chip ejector according to an embodiment of the present inventive concept. To the extent that an element has not been described in detail, it may be assumed that the element is at least similar to corresponding elements that have been described in previous FIGS. 1 to 8.

Referring to FIGS. 9 and 10, the chip ejector may be located at a first position S1, and the first position S1 may correspond to the horizontal width of a chip 400 of FIG. 9. Referring to FIG. 1 together with FIGS. 9 and 10, the chip ejector 100 may overlap seven holes among the plurality of holes H. Here, when the seven holes H are arranged as a first hole, a second hole, a third hole, a fourth hole, a fifth hole, a sixth hole, and a seventh hole respectively from the left, the air pins 137 may be respectively inserted into the third hole, the fourth hole, and the fifth hole. In an embodiment of the present inventive concept, the air pins 137 may be arranged adjacent to each other without the path 135-1 having the cap 139 between the air pins 137. When the seven paths 135-1 of the air inlet pipe 135 are arranged as a first path, a second path, a third path, a fourth path, a fifth path, a sixth path, and a seventh path from the left, the air pins 137 may be respectively inserted into the third path, the fourth path, and the fifth path. The number of inserted air pins 137 may be plural, but the present inventive concept is not necessarily limited thereto.

The cap 139 may be disposed on the upper surface of the path 135-1 into which the air pin 137 is not inserted. The caps 139 may be disposed on the first path, the second path, the sixth path, and the seventh path. The pressurized air flow F_130 generated by the pressurized air provided by the pressurization source 131 may move along the air pins 137 inserted into the third path, the fourth path, and the fifth path. In the first path, the second path, the sixth path, and the seventh path in which the caps 139 are arranged, the pressurized air flow F_130 may move but not reach the lower surface of the mount tape 200 due to the caps 139 that isolate the air inlet pipe 135 from the inner space 125 of the chamber 101.

The first hole, the second hole, the sixth hole, and the seventh hole into which the air pins 137 are not inserted may be provided with the vacuum flow F_120 and function as the suction holes H1 (FIG. 1).

The cross-sectional area of the chip 400 in FIG. 9 may be greater than the cross-sectional areas of the holes into which the air pins 137 are inserted. The mount tape 200 disposed on the lower surface of the chip 400 may be raised by a certain vertical level. The generated pressurized air flow F_130 may raise the mount tape 200 only in areas corresponding to the horizontal cross-sectional areas of the air pins 137. While the mount tape 200 is rising, the vacuum source 121 may provide the vacuum pressure to the hole into which the air pin 137 is not inserted, for example, the suction hole H1 (FIG. 1), thereby forming the vacuum flow F_120. In an embodiment of the present inventive concept, the pressurization unit 130 and the vacuum unit 120 may be configured to operate together. Therefore, even if the pressurized air is provided by the pressurization source 131, the mount tape 200 in a region corresponding to the hole into which the air pin 137 is not inserted may not rise. For example, only a region of the mount tape 200 may be raised. For example, when the pressurized air is provided to the air pin 137, the chip ejector 100 may change to the state as shown in the diagram. In addition, the horizontal area of the raising mount tape 200 may be less than the horizontal area of the chip 400.

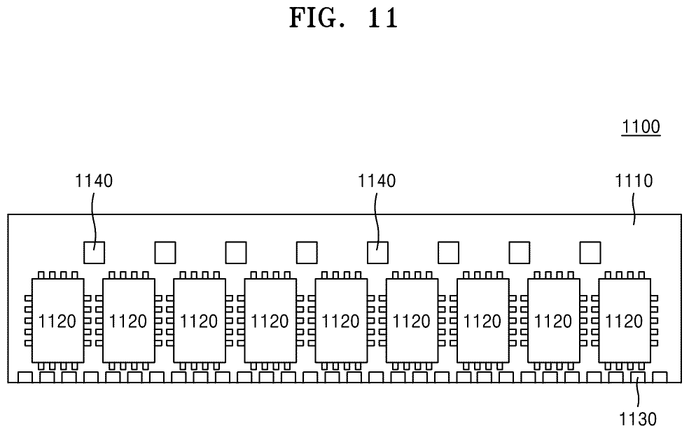

FIG. 11 is a plan view showing a memory module 1100 including picked-up chips according to an embodiment of the present inventive concept.

Referring to FIG. 11, the memory module 1100 may include a module substrate 1110 and a plurality of semiconductor devices 1120 attached to the module substrate 1110.

The semiconductor devices 1120 may include the chips that are picked up according to an embodiment of the present inventive concept. For example, the semiconductor devices 1120 may include the chips 400 illustrated in FIGS. 2 to 10.

A connector 1130 that may be inserted into a socket of a motherboard is located on one side of the module substrate 1110. A ceramic decoupling capacitor 1140 is disposed on the module substrate 1110. The memory module 1100 according to an embodiment is not necessarily limited to the configuration illustrated in FIG. 11 and may be manufactured in various forms.

The semiconductor devices 1120 of the memory module 1100 may have fine pitch connection terminals and thus achieve a compact size and wide input/output (I/O). Therefore, the memory module 1100 having high capacity and high performance may be provided.

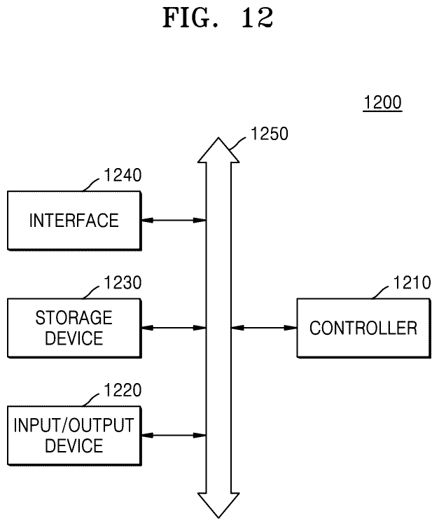

FIG. 12 is a configuration diagram showing a system 1200 including picked-up chips according to an embodiment of the present inventive concept.

Referring to FIG. 12, the system 1200 includes a controller 1210, an input/output device 1220, a storage device 1230, and an interface 1240. The system 1200 may include a mobile system or a system that transmits information to or receives information from another system. In some embodiments, the mobile system may include a personal digital assistant (PDA), a portable computer, a web tablet, a wireless phone, a mobile phone, a digital music player, or a memory card. The controller 1210 may control execution programs in the system 1200 and include a microprocessor, a digital signal processor, a microcontroller, or other devices similar thereto.

The input/output device 1220 may be used to input or output data of the system 1200. The system 1200 may be connected to an external device, for example, a personal computer or a network that may exchange data with the external device using the input/output device 1220. The input/output device 1220 may include, for example, a keypad, a keyboard, or a display.

The storage device 1230 may store code and/or data for operation of the controller 1210 or the data processed by the controller 1210. The storage device 1230 may include the semiconductor device according to an embodiment of the present inventive concept.

The interface 1240 may include a data transmission path between the system 1200 and an external another device. The controller 1210, the input/output device 1220, the storage device 1230, and the interface 1240 may communicate with each other via a bus 1250. Thes system 1200 may be used in a mobile phone, an MPEG Audio Layer 3 (MP3) player, a navigation unit, a portable multimedia player (PMP), a solid state disk (SSD), or household appliances.

The controller 1210 or the storage device 1230 of the system 1200 may have fine pitch connection terminals and thus achieve a compact size, multi-functionality, and wide I/O. Therefore, the system 1200 with increased capacity may be provided.

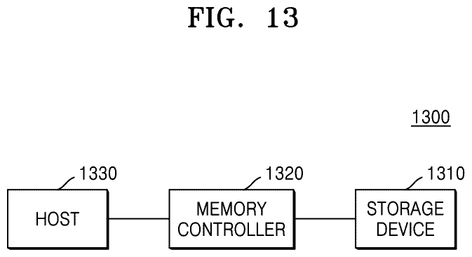

FIG. 13 is a configuration diagram showing a memory card 1300 including picked-up chips according to an embodiment of the present invention.

Referring to FIG. 13, the memory card 1300 includes a storage device 1310 and a memory controller 1320.

The storage device 1310 may store data. In embodiments of the present inventive concept, the storage device 1310 may have non-volatile characteristics, and thus, stored data may remain intact even if the power supply thereto is interrupted.

The memory controller 1320 may read data stored in the storage device 1310 or store data in the storage device 1310 in response to a read/write request from a host 1330.

The storage device 1310 may have fine pitch connection terminals and thus achieve a compact size and wide I/O. Therefore, the memory card 1300 with increased capacity may be provided.

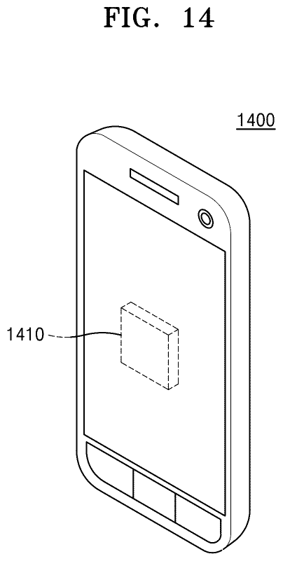

FIG. 14 is a perspective view schematically showing an electronic device to which picked-up chips are applied according to an embodiment of the present inventive concept.

Referring to FIG. 14, an example in which the system 1200 of FIG. 12 is applied to a mobile phone 1400 is shown. The mobile phone 1400 may include a system-on-chip 1410.

The mobile phone 1400 may include the system-on-chip 1410 that has fine pitch connection terminals and thus achieves a compact size, multi-functionality, and wide I/O. Therefore, the mobile phone 1400 may have increased performance while being minimized in size.

While the inventive concept has been particularly shown and described with reference to embodiments thereof, it will be understood that various changes in form and details may be made therein without departing from the spirit and scope of the present inventive concept.

What is claimed is:

1. A chip ejector comprising:
a chamber including an inner space;
a holder disposed on the chamber, extending along a first direction and a second direction perpendicular to the first direction, and having an upper surface and a lower surface opposite to the upper surface;
a plurality of holes formed in the holder along a vertical direction, which is perpendicular to the first direction and the second direction and spaced apart from each other in the first direction, and the second direction; and
a pressurization unit providing pressurized air to a mount tape that is disposed on the holder,
wherein the pressurization unit comprises:
at least one air pin inserted into at least one hole among the plurality of holes along the vertical direction and having a discharge hole extending along the vertical direction; and
an air inlet pipe fastened to the air pin and comprising at least one path through which a pressurized air flow is provided to the air pin.

2. The chip ejector of claim 1, wherein the pressurization unit further comprises:
a pressurization source providing the pressurized air to the air inlet pipe; and
a pressurization valve connected to the pressurization source and regulating an amount of the pressurized air.

3. The chip ejector of claim 1, wherein a hole, into which the air pin is not inserted among the plurality of holes corresponding to an area of the chamber, is a suction hole, and
wherein the chip ejector further comprises a vacuum unit providing a vacuum flow to the suction hole and the inner space of the chamber connected to the suction hole.

4. The chip ejector of claim 3, wherein the vacuum unit comprises:
a vacuum source generating vacuum pressure; and
a vacuum valve connected to the vacuum source and regulating a level of the vacuum pressure.

5. The chip ejector of claim 3, wherein the pressurization unit and the vacuum unit are configured to operate together.

6. The chip ejector of claim 1, wherein the pressurization unit further comprises a cap disposed on an upper surface of a path to which the air pin is not fastened among the plurality of paths provided by the air inlet pipe.

7. The chip ejector of claim 6, wherein the cap is configured to prevent the pressurized air flow from leaking from the air inlet pipe into the inner space of the chamber.

8. The chip ejector of claim 1, wherein a vertical level of an upper surface of the air pin is same as the vertical level of the upper surface of the holder.

9. The chip ejector of claim 1, wherein a horizontal width of the air pin is equal to a horizontal width of the hole, and
wherein a position of the hole into which the air pin is inserted is determined according to a size of a chip attached to an upper surface of the mount tape.

10. The chip ejector of claim 1, wherein, when the air pin is provided in plurality,
the plurality of air pins are respectively inserted into the holes different from each other, and
the plurality of air pins are spaced apart from each other along the first direction.

11. A chip ejector comprising:
a holder extending along a first direction and a second direction perpendicular to the first direction and having a plurality of holes passing therethrough along a vertical direction;
a mount tape disposed on an upper surface of the holder;
a chip disposed on an upper surface of the mount tape;
a picker unit disposed above the chip and vacuum-suctioning the chip to separate the chip from the mount tape;
an air pin inserted into at least one hole among the plurality of holes and configured to provide pressurized air to a lower surface of the mount tape;
an air inlet pipe on which the air pin is mounted to form a plurality of paths through which the pressurized air flows;
a pressurization source providing the pressurized air to the air inlet pipe;
a chamber disposed below the holder and forming an inner space; and
a vacuum unit configured to provide vacuum pressure to the lower surface of the mount tape.

12. The chip ejector of claim 11, wherein the picker unit comprises a picker vacuum part providing vacuum pressure to an upper surface of the chip,
wherein the picker vacuum part is spaced apart from the upper surface of the chip by a distance, and
wherein a horizontal width of the picker vacuum part is less than a horizontal width of the chip.

13. The chip ejector of claim 11, wherein the air pin comprises a discharge hole through which the pressurized air moves, and
wherein a horizontal width of the discharge hole is constant across all vertical levels.

14. The chip ejector of claim 13, wherein a vertical level of an upper surface of the air pin is same as a vertical level of the upper surface of the holder, and
wherein the horizontal width of the discharge hole is less than a horizontal width of the hole.

15. The chip ejector of claim 11, wherein, when a hole, into which the air pin is not inserted among the plurality of holes corresponding to an area of the chamber, is defined as a suction hole, and
wherein the vacuum unit is configured to provide a vacuum flow to the suction hole and the inner space of the chamber connected to the suction hole.

16. The chip ejector of claim 15, further comprising a cap mounted on an upper surface of a path to which the air pin is not fastened among the plurality of paths formed in the air inlet pipe,
wherein the cap is configured to prevent the vacuum flow from leaking from the inner space of the chamber to the air inlet pipe.

17. The chip ejector of claim 11, wherein a horizontal width of the air pin is equal to a horizontal width of the hole, and
wherein a position of the hole into which the air pin is inserted is determined according to a size of the chip attached to the upper surface of the mount tape.

18. The chip ejector of claim 11, wherein a horizontal position of the path in the air inlet pipe corresponds to a horizontal position of the hole in the holder.

19. A chip ejector comprising:
a chamber forming an inner space;
a holder disposed above the chamber, and having a plurality of holes passing therethrough along a vertical direction;
a mount tape disposed on an upper surface of the holder;
a chip disposed on an upper surface of the mount tape;
a picker unit disposed above the chip and vacuum-suctioning the chip to separate the chip from the mount tape;
a pressurization unit providing pressurized air to the mount tape disposed on the holder; and
a vacuum unit providing vacuum pressure to a lower surface of the mount tape,
wherein the pressurization unit comprises:
an air pin inserted into at least one hole among the plurality of holes along the vertical direction and having a discharge hole extending in the vertical direction;
an air inlet pipe on which the air pin is mounted to form a plurality of paths through which the pressurized air flows;
a pressurization source providing the pressurized air to the air inlet pipe; and
a pressurization valve connected to the pressurization source and regulating an amount of the pressurized air,
wherein a hole, into which the air pin is not inserted among the plurality of holes corresponding to an area of the chamber, is a suction hole,
wherein the vacuum unit comprises:
a vacuum source generating the vacuum pressure in the suction hole and the inner space of the chamber connected to the suction hole; and
a vacuum valve connected to the vacuum source and regulating a level of the vacuum pressure.

20. The chip ejector of claim 19, wherein the pressurization unit further comprises a cap mounted on an upper surface of a path to which the air pin is not fastened among the plurality of paths provided by the air inlet pipe,
wherein the cap isolates the air inlet pipe from the inner space of the chamber and prevents a flow of the pressurized air from mixing with a flow of vacuum formed by the vacuum pressure.
